(19) United States
(12) Patent Application Publication
(10) Pub. No.: US 2024/0048119 A1
(43) Pub. Date: Feb. 8, 2024

(54) ACOUSTIC WAVE DEVICE

(71) Applicant: Sanan Japan Technology Corporation, Tokyo (JP)

(72) Inventors: Yutaka Kadogawa, Tokyo (JP); Hirofumi Nakamura, Tokyo (JP); Koichi Kumagai, Tokyo (JP)

(73) Assignee: Sanan Japan Technology Corporation, Tokyo (JP)

(21) Appl. No.: 18/366,226

(22) Filed: Aug. 7, 2023

(30) Foreign Application Priority Data
Aug. 8, 2022 (JP) 2022-126611

(51) Int. Cl. H03H 9/02; H03H 9/25; H03H 3/02

(52) U.S. Cl. CPC H03H 9/02543; H03H 9/25; H03H 3/02

(57) ABSTRACT

An acoustic wave device includes a resonator formed on one surface of a device chip; a support layer formed so as to surround the resonator on the one surface; a cover layer formed on the support layer and cooperating with the device chip and the support layer to form a cavity for hermetically sealing the resonator; and the cover layer on the one cavity is curved so that a forming side of the resonator is a curved inner side.

### CROSS-REFERENCE TO RELATED APPLICATION(S)

This application claims priority to Japanese Application No. 2022-126611, filed Aug. 8, 2022, which are incorporated herein by reference, in their entirety, for any purpose.

### BACKGROUND OF THE INVENTION

### Field of the Invention

The present invention relates to an improvement of an acoustic wave device suitable for use as a frequency filter or the like in a mobile communication device or the like.

### Background Art

An acoustic wave device D used as a frequency-filter or the like in a mobile-communication device or the like is shown in FIG. 9. FIG. 9 shows a device chip 100, a resonator 101 formed on one surface of the device chip 100, a support layer 102 made of a synthetic resin formed on the device chip 100, a cover layer 103 made of a synthetic resin which is formed on the support layer 102 and a cavity 104 (internal space, hollow structure part) for hermetically sealing the resonator 101, and a bump 105 electrically connected to a circuit formed on the device chip 100 including the resonator 101.

The acoustic wave device D is mounted on a module board Ma together with other electronic devices by using the bumps 105 to form a module M. The bumps 105 are typically bonded to electrodes formed on the module substrate Ma by ultrasonic bonding or the like, and after the bonding, the acoustic wave device D is sealed by a sealing resin layer Mb formed on the module substrate Ma. Since the gap S formed by the bumps 105 is formed between the acoustic wave device D and the module substrate Ma, the sealing resin layer Mb also enters between the cover layer 103 of the acoustic wave device D and the module substrate Ma. Therefore, when the sealing resin layer Mb is formed, the cover layer 103 is subjected to a force in a direction of narrowing the distance between the cover layer 103 and the device chip 100.

When the cover layer 103 comes into contact with the device chip 100 side in the cavity 104 due to the action of such force, the function of the acoustic wave device D is hindered.

### SUMMARY OF THE INVENTION

The main problem to be solved by the present invention is to provide an acoustic wave device of this type with a function of preventing, as much as possible, a situation in which the cover layer constituting the acoustic wave device comes into contact with one surface or a resonator of the device chip by the force applied when the sealing resin layer is formed on the module substrate after the acoustic wave device is mounted on the module substrate, without complicating the structure of the acoustic wave device and the manufacturing process thereof.

In some examples, an acoustic wave device includes a resonator formed on one surface of a device chip, a support layer formed so as to surround the resonator on the one surface, a cover layer formed on the support layer and cooperating with the device chip and the support layer to form a cavity for hermetically sealing the resonator, the cover layer on the at least one cavity is curved so that a forming side of the resonator is a curved inner side.

### BRIEF DESCRIPTION OF THE DRAWINGS

FIG. 1 is a plan view of an acoustic wave device 10 according to an embodiment of the present disclosure;

FIG. 2 is a cross-sectional view of the acoustic wave device and is shown in a cross-sectional view at a A-A position in FIG. 1;

FIG. 3 is a cross-sectional view of the acoustic wave device and is shown in a cross-sectional view at a B-B position in FIG. 1;

FIG. 4 is a cross-sectional view of the acoustic wave device and is shown in a cross-sectional view at a C-C position in FIG. 1;

FIG. 5 shows an example of a resonator formed in a device chip of the acoustic wave device;

FIG. 6 shows an example of a circuit formed in a device chip of the acoustic wave device;

FIG. 7 is a cross-sectional view showing each step of the manufacturing process of the acoustic wave device, and proceeds in the order of part a, part b, part c, part d, part e, part f, part g, and part h;

FIG. 8 is a cross-sectional view of a main part of a module including the acoustic wave device; and

FIG. 9 is a cross-sectional view of an example of a module including a conventional acoustic wave device.

### DETAILED DESCRIPTION

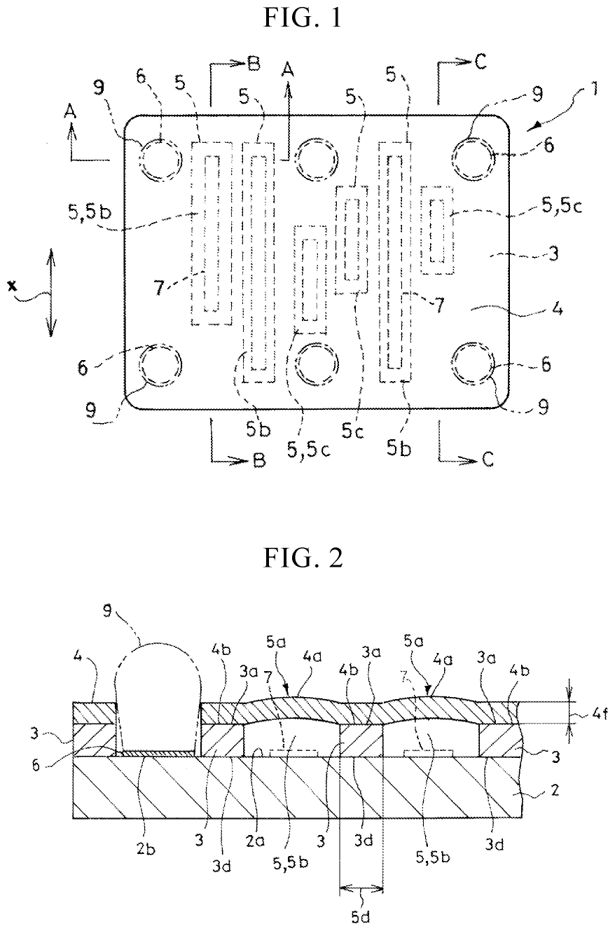

Embodiments will be described with reference to the accompanying drawings. In the drawings, the same or corresponding parts are denoted by the same reference numerals. Duplicate descriptions of such portions may be simplified or omitted. Hereinafter, an exemplary embodiment of the present invention will be described with reference to FIGS. 1 to 8. The acoustic wave device 1 according to this embodiment is suitable for use as a frequency filter or the like in a mobile communication device or the like.

### Embodiment.

Embodiment 1.

Such an acoustic wave device 1 includes a device chip 2, a resonator 7 formed on a surface 2a of the device chip 2, a support layer 3 (wall) formed so as to surround the resonator 7 on the surface 2a, and a cover layer 4 (roof) formed on the support layer 3 and forming a cavity 5 (internal space, hollow structure) for hermetically sealing the resonator 7 cooperating with the device chip 2 and the support layer 3.

Typically, the device chip 2 is formed in a rectangular plate shape having a side length of 0.5 to 1 mm and a thickness of 0.15 to 0.2 mm. Also, typically, the support layer 3 is formed such that the thickness 3c is 10 to 30 micrometers.

Typically, the cover layer 4 is formed so that the thickness 4f may be set to 15-35 micrometers. An acoustic wave device 1 comprising of these elements typically has a thickness approximately of 0.25 to 0.35 mm including a bump height.

The planar structure of the acoustic wave device is shown in FIG. 1. Reference numeral 7 denotes the resonator, reference numeral 5 denotes the cavity, reference numeral 9 denotes the bump, reference numeral 4 denotes the cover layer, and reference numeral 6 denotes a through hole penetrating through the support layer 3 and the cover layer 4 outside the formation region of the cavity 5.

A plurality of resonators 7 are formed on the surface 2a of the device chip 2. Regions of the resonators 7 formed on the surface 2a of the device chip 2 are surrounded by the supporting layer 3, and are covered with the covering layer 4 formed on the support layer 3, whereby the acoustic wave device includes the plurality of cavities 5.

A cross-sectional view of the acoustic wave device is shown in FIG. 2. In the drawing, reference numeral 2b denotes a bump pad (electrode pad). The bump pad 2b is connected to a line of circuit including the resonator 7 formed on the device chip 2. The bump pad 2b is in the through-hole 6. A bump 9 made of a conductive metal such as gold is formed in the through hole 6.

The device chip 2 has a function of propagating an elastic wave. Typically, lithium tantalate or lithium niobate is used for the device chip 2. The device chip 2 may be formed by bonding sapphire, silicon, alumina, spinel, quartz, glass, or the like.

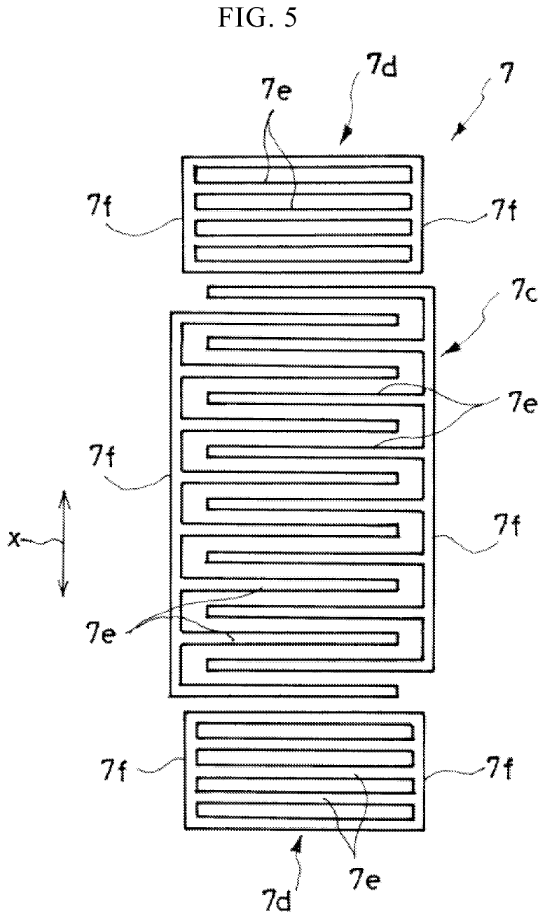

FIG. 5 shows an example of the resonator 7. The resonator 7 has an IDT electrode 7c and reflectors 7d. The reflectors 7d are formed so as to sandwich the IDT electrode 7c. The IDT electrode 7c is formed of an electrode pair, and the electrode pair is formed by a plurality of electrode fingers 7e arranged in parallel and connected by a busbar 7f at one end thereof so as to cross the length direction of the electrode fingers 7e in the propagation direction x of the acoustic wave. The reflector 7d is formed by connecting ends of a plurality of electrode fingers 7e by a busbar 7f arranged in parallel so as to cross the length direction in the propagation direction x of the acoustic wave.

The resonator 7 is typically formed of a conductive metal film formed by a photolithography technique.

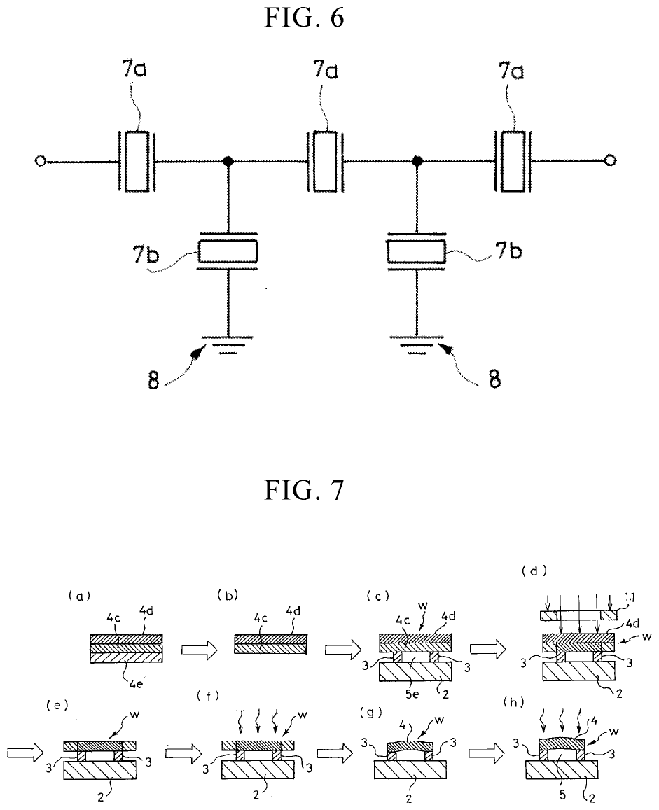

FIG. 6 shows a concept of an example of a circuit formed on the device chip 2. Reference numeral 7a denotes a resonator connected in series between the input/output ports, reference numeral 7b denotes a resonator connected in parallel between the input/output ports, and reference numeral 8 denotes a ground. The number and arrangement of the resonators 7a, 7b may be changed as necessary. That is, the ladder filter is configured by the circuit of FIG. 6.

In the acoustic wave device according to this embodiment, the cover layer 4 on at least one of the cavities 5 is curved so that the forming side of the resonator 7 is curved inside.

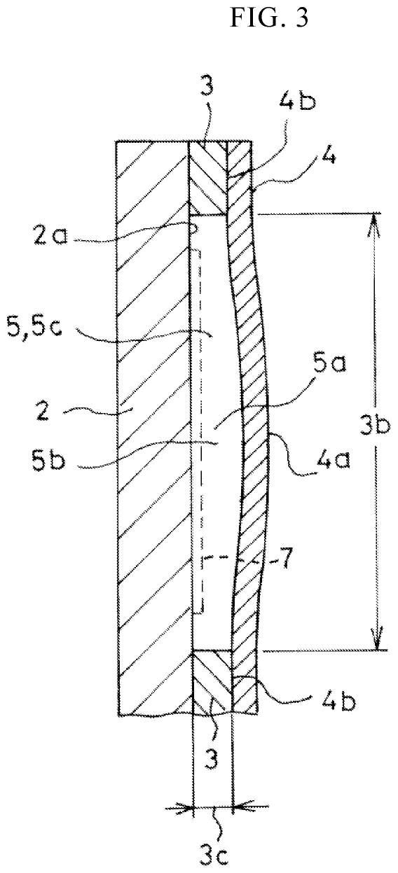

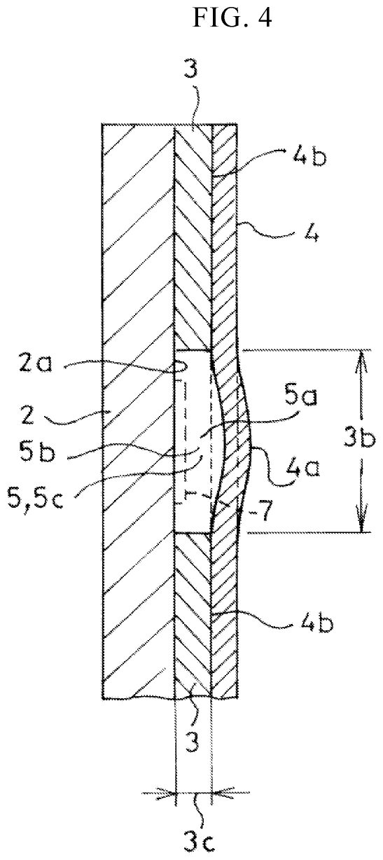

In the illustrated embodiment, the cover layer 4 is curved so as to form a top 4a in the central region 5a of the cavity 5 in a cross-sectional view of the acoustic wave device 1 in a direction that is parallel to any one side of the device chip 2 having a rectangular outline (e.g. FIG. 2, a cross-sectional view along the lateral direction in FIG. 1). And, in the cross-sectional view of the acoustic wave device 1 in a direction perpendicular to the one side, the cover layer 4 is also curved so as to form a top 4a in the central region 5a of the cavity 5 (e.g. FIG. 3 and FIG. 4., a cross-sectional view along the vertical direction in FIG. 1).

More specifically, the cover layer 4, which is a so-called cover of one cavity 5, is curved so as to gradually increase the distance between the surface 2a of the device chip 2 as it approaches the central region 5a of the cavity 5 from a junction point 4b with respect to a protruding end portion 3a of the support layer 3 (as shown in FIG. 2), which is a so-called wall of one cavity 5, from the device chip 2. That is, the cover layer 4 positioned on the resonator 7 bulges toward the outside of the cavity 5, that is, toward the outside of the acoustic wave device, and the outer surface of the cover layer 4 is a three-dimensional curved surface.

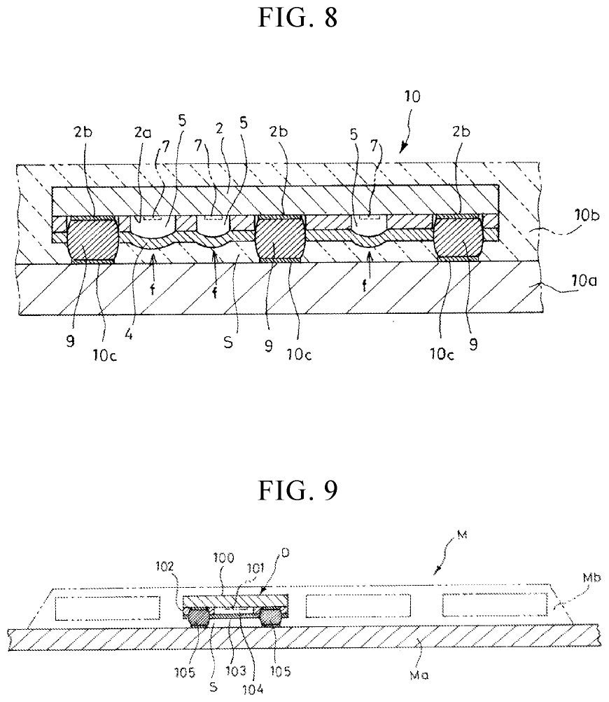

As shown in FIG. 8, in many cases, the acoustic wave device 1 is mounted on a module board 10a together with other electronic devices by using the bumps 9 to constitute the module 10. The bumps 9 are typically bonded to electrodes of the module board 10a by ultrasonic bonding or the like, and after the bonding, the acoustic wave device 1 is sealed by a sealing resin layer 10b formed on the module board 10a. Since a gap S (see FIG. 8) formed by the bumps 9 is formed between the acoustic wave device 1 and the module board 10a, the sealing resin layer 10b also enters between the cover layer 4 of the acoustic wave device 1 and the module board 10a. Therefore, when the sealing resin layer 10b is formed, a force f (see FIG. 8) in a direction to narrow the distance between the cover layer 4 and the surface 2a of the device chip 2 is applied to the cover layer 4. When the cover layer 4 contacts the surface 2a of the device chip 2 or the resonator 7 in the cavity 5 due to the action of the force f, the function of the acoustic wave device 1 is inhibited. In the acoustic wave device 1 according to this embodiment, since the cover layer 4 is curved in advance as described above, the cover layer 4 easily resists the force f, and even if it is deformed, it is possible to prevent the device chip 2 from being displaced toward the surface 2a or the resonator 7. Thus, the yield of the module 10 including the acoustic wave device 1 can be improved.

In the illustrated embodiment, the acoustic wave device 1 includes a plurality of the cavities 5, and in the cavities 5, the cover layer 4 is curved so that the surface 2a of the device chip 2 is a curved inner side. In this way, it is possible to prevent deformation of the cover layer 4 caused by the force fin each of the plurality of the cavities 5.

In an illustrated example, the acoustic wave device 1 is provided with a plurality of the cavities 5, and at least one of a plurality of the cavities 5 is the large room cavity 5b which makes the distance 3b (see FIG. 3) between the opposed support layers 3 which constitute the large room cavity 5b more than 6 times to 15 times of the thickness 3c of the support layer 3 of the direction which intersects perpendicularly with the surface 2a of the device chip 2 (refer to FIG. 3).

In addition, at least one of the plurality of cavities 5 is a small room cavity 5c in which a distance 3b between the opposed support layers 3 constituting the cavity 5 is less than six times the thickness 3c of the support layer 3 (see FIG. 4). At least in the large room cavity 5b, the cover layer 4 is curved so that a forming side of the resonator 7 is a curved inner side.

In the illustrated embodiment, each of the plurality of cavities 5 positions the resonator 7 one by one in the cavity 5 and has a distance 3b between the support layers 3 facing each other in the propagation direction x of the acoustic wave bigger than the distance 3b between the support layer 3 facing each other in a direction perpendicular to the propagation direction x, a plurality of cavities 5 in a state of plan view of the acoustic wave device 1 is configured to have a length and width, respectively (see FIG. 1). Although not shown, two or more resonators 7 may be positioned in one cavity 5.

In the large room cavity 5b, the distance 3b between the opposed support layers 3 is large, so that the displacement is large when the cover layer 4 is deformed due to the force f increases. At least in the large room cavity 5, it is possible to achieve the purpose of the present invention to improve the yield of the module 10 configured to include the acoustic wave device 1 by bending the cover layer 4 as described above. From the other viewpoint, according to the present invention, it is easy to prepare the large room cavity 5b as described above in the acoustic wave device 1. In the illustrated example, although the cover layer 4 is curved as described above in the small room cavity 5c, the cover layer 4 of the small room cavity 5c may be formed flat, that is, parallel to the surface 2a of the device chip 2 depending on the magnitude of the force f (the outline of the cover layer 4 when flat is shown by a dotted line in FIG. 4).

The cover layer 4 is preferably made of a thermosetting sheet material (e.g. planar material) 4c having a thickness 4f of 15 to 35 micrometers. In any case, when the thickness 4f of the cover layer 4 is less than 15 micrometers, the cover layer 4 becomes fragile. On the other hand, when the thickness 4f of the cover layer 4 is more than 35 micrometers, it is difficult to bend and deform the cover layer 4 in a baking step described later. As the planar material 4c, it is preferable to use a material having a constant adhesive strength at room temperature and having a function of removing an unnecessary part through exposure and development in a photolithography technique.

On the other hand, the support layer 3 is preferably made of a synthetic resin which is easily formed on the surface 2a of the device chip 2 and is compatible with the cover layer 4. The support layer 3 has a base 3d (see FIG. 2) joined to the surface 2a of the device chip 2 and a protruding end 3a joined to the cover layer 4 and is formed so as to protrude from the surface 2a in a direction perpendicular to the surface 2a of the device chip 2. The support layer 3 constitutes so-called side wall of the cavity 5.

In the illustrated example, a portion between the cavities 5 adjacent to each other is made solid by the support layer 3. The distance 5d between the adjacent cavities 5 is preferably equal to or greater than the thickness 4f of the cover layer 4.

The acoustic wave device 1 described above can be appropriately and rationally manufactured by the following method. The main part of the manufacturing step of the acoustic wave device 1 according to this embodiment is shown in FIG. 7. Note that only a part of the wafer before dicing is represented as the device chip 2 in FIG. 7 for convenience.

First, a resonator 7 (not shown) is formed on a surface 2a of the device chip 2 (step 1/not shown). Typically, a plurality of resonators 7 are formed.

Next, the support layer 3 is formed on the surface 2a of the device chip 2 in a region other than the region where the resonator 7 is formed (step 2/not shown).

Subsequently, the cover layer 4 is formed on the support layer 3 (Step 3/FIG. 7, parts (a) to (h)). Step 3 is a lamination process (Steps 3-1 (FIG. 7, part (a)) to 3-5 (FIG. 7, part (e))), and a bake process (Step 3-6 (FIG. 7, part (f))), a developing step (step 3-7 (FIG. 7, part (g))), and a curing step (step 3-8 (FIG. 7, part (h))).

In the laminating step, a thermosetting sheet 4c is placed on the support layer 3 in an environment in which the temperature is 30° C. to 60° C. and the atmospheric pressure is 0.3 MPa or less.

First, a base film 4d is prepared on the upper surface of the planar material 4c serving as the cover layer 4, and an original film having a cover film 4e is prepared on the lower surface (step 3-1/FIG. 7, part (a)). As the planar material 4c, a thermosetting material having a constant adhesive strength at room temperature and having a function of being removed an unnecessary part through exposure and development in a photolithography technique is used.

Next, the cover film 4e is peeled off from the original film (Step 3-2/FIG. 7, part (b)).

Next, the lower surface of the planar material 4c is adhered to the protruding end portion 3a of the support layer 3 formed so as to surround the resonator 7 (steps 3-3/FIG. 7, part (c)). As a result, a temporary cavity 5e is formed above the resonator 7. If the distance 5d between the adjacent cavities 5 is set to be more than twice the thickness 4f of the cover layer 4, the adhesive margin between the protruding end portion 3a of the support layer 3 to be solid between the adjacent cavities 5 and the cover layer 4 is secured large, it is possible to maintain high airtightness of the temporary cavity 5e during the baking process.

Then, the planar material 4c is exposed (steps 3-4/FIG. 7, part (d)). Reference numeral 11 denotes a photomask.

Next, the base film 4d is peeled off from the upper surface of the planar material 4c (Step 3-5/FIG. 7, part (e)).

In a bake process, a workpiece w (intermediate product) which passed the aforementioned lamination process (Step 3-6/FIG. 7, part (f)) is warmed for 7 minutes to 12 minutes by 100° C. to 120° C. The planar material 4c is configured to increase plasticity and not harden at such temperatures. For this reason, the cover layer 4 as a part of the planar material 4c which constitutes the temporary cavity 5 by volume expansion of the gas in the temporary cavity 5 can be curved like FIG. 7, part (g). In the large room cavity 5b, the deformation of the cover layer 4 is large. And, in the small room cavity 5c, it is small or it can be seen that there is practically no deformation.

Next, the unnecessary part is removed from the planar material 4c by development (Step 3-7/FIG. 7, part (g)).

In the curing step, the developed workpiece is heated at 150° C. to 200° C. for 45 minutes to 90 minutes (step 3-8/FIG. 7, part(h)). The planar material 4c is configured to be cured at such a temperature. As a result, the temporary cavity 5e becomes the cavity 5. The curved shape of the cover layer 4 formed by the baking process is maintained.

A plurality of acoustic wave devices 1 are produced from the workpiece w by dicing after the curing step.

While several aspects of at least one embodiment have been described, it is to be understood that various modifications and improvements will readily occur to those skilled in the art. Such modifications and improvements are intended to be part of the present disclosure and are intended to be within the scope of the present disclosure.

It is to be understood that the embodiments of the methods and apparatus described herein are not limited in application to the structural and ordering details of the components set forth in the foregoing description or illustrated in the accompanying drawings. Methods and apparatus may be implemented in other embodiments or implemented in various manners.

Specific implementations are given here for illustrative purposes only and are not intended to be limiting.

The phraseology and terminology used in the present disclosure are for the purpose of description and should not be regarded as limiting. The use of “including,” “comprising,” “having,” and variations thereof herein means the inclusion of the items listed hereinafter and equivalents thereof, as well as additional items.

The reference to “or” may be construed so that any term described using “or” may be indicative of one, more than one, and all of the terms of that description.

References to front, back, left, right, top, bottom, and side are intended for convenience of description. Such references are not intended to limit the components of the present disclosure to any one positional or spatial orientation. Accordingly, the foregoing description and drawings are by way of example only.

What is clamed is

1. An acoustic wave device comprising:
a device chip;
a resonator formed on a surface of the device chip;
a support layer formed on the surface so as to surround the resonator;
a cover layer formed on the support layer and cooperating with the device chip and the support layer to form a cavity for hermetically sealing the resonator;
wherein the cover layer on the cavity is curved so that a forming side of the resonator is a curved inner side.

2. The acoustic wave device according to claim 1, further comprising a plurality of cavities comprising the cavity, and the cover layer is curved so that the surface of the device chip is curved inner side in each of the cavities.

3. The acoustic wave device according to claim 1, further comprising a plurality of cavities comprising the cavity, wherein at least one of the plurality of the cavities is a large room cavity whose distance between the opposed support layers is 6 times to 15 times of a thickness of the support layer in a direction orthogonal to the surface of the device chip, wherein at least another one of the plurality of the cavities is a small room cavity whose distance between the opposed support layers is less than 6 times of the thickness of the support layer, and wherein the cover layer is curved so that a forming side of the resonator is curved inside in the large room cavity.

4. The acoustic wave device according to claim 1, wherein the cover layer is made of a planar material made of a thermosetting resin having a thickness of 15 μm to 35 μm.

5. The acoustic wave device according to claim 2, wherein the cover layer is made of a planar material made of a thermosetting resin having a thickness of 15 μm to 35 μm.

6. The acoustic wave device according to claim 3, wherein the cover layer is made of a planar material made of a thermosetting resin having a thickness of 15 μm to 35 μm.
